(19) United States
(12) Patent Application Publication
(10) Pub. No.: US 2012/0288803 A1
(43) Pub. Date: Nov. 15, 2012

(54) MANUFACTURING DEVICE OF OPTICAL DEFLECTOR AND MANUFACTURING METHOD OF THE SAME

(75) Inventor: Chao-Yi TAI, Jhongli City (TW)

(73) Assignee: National Central University, Jhongli City (TW)

(21) Appl. No.: 13/316,175

(22) Filed: Dec. 9, 2011

(30) Foreign Application Priority Data
May 11, 2011 (TW) 100116577

(51) Int. Cl. G03F 7/20; G03B 27/42

(52) U.S. Cl. 430/321; 355/53

(57) ABSTRACT

A manufacturing device of optical deflectors and a manufacturing method of the same are revealed. The manufacturing device includes a movable work platform, a substrate, a lens and a femtosecond laser source. The substrate is disposed on the movable work platform and is coated with a photoresist polymer film. The lens is arranged at one side of the movable work platform. The femtosecond laser source produces a femtosecond laser that passes through the lens and projects onto the photoresist polymer film at a non-focal position of the lens so as to produce an optical deflector. The optical deflector is produced only by the femtosecond laser projected onto the photoresist polymer film at the non-focal position. Thus the production efficiency of the optical deflector is improved.

### BACKGROUND OF THE INVENTION

1. Field of the Invention

The present invention relates to a manufacturing device of a polymer component and a manufacturing method of the same, especially to a manufacturing device of optical deflectors and a manufacturing method of the same.

2. Descriptions of Related Art

As to the light, people changes from knowing nothing, to understanding the nature of the light, and finally controlling direction and behavior of the light in some degrees. The progress is quite slow. Even nowadays scientists still keep exploring the mysterious light that is linear and nothing can travel faster than the light. The development of elements related to the optical field is also quite slow. In this information explosion era we live in today, people are eager to control the light due to its broadband property.

Light is transmitted at high speed-about 300000 km/sec. Light has good coherence and they do not cause interference to each other during transmission. The transmission of light is linear so that the light changes directions due to reflection. During the transmission processes, some measures that prevent transmittance and scattering are taken.

The most popular topic in the research is integrated optics. Various optical devices are disposed in thin-film form to become an integrated optical circuit that is produced into different products. The goal of integrated optics (IO) is to develop miniaturized optical devices of high functionality such as light generation, modulation, switching, and detection on a common substrate. The integrated optical element not only has optical advantages of large capacity, no electromagnetic interference (EMI), parallel processing of information but also have economical benefits and reliability like advantages of general integrated circuits. The vibration problem occurred in conventional optical experiments disappears after the elements being integrated. Compared with conventional optical elements, the compact size of the integrated optical element can achieve various interactions more efficiently. For example, an electro-optic effect is achieved by lower voltage. And the optical signals are modulated more efficiently by the electro-optic effect. After long-term development and progress, the manufacturing techniques and transmission performance of the circuit board are at their limits for meeting requirements of high density interconnection, high frequency development of signal transmission, and refinement of wires. Thus integrated optics has advantages in these fields of application.

Within integrated optics, the optical deflector is one of the important elements. The optical deflector is used in transmission of optical signals. Generally, optical deflectors are produced by photolithography. The designed pattern is produced into a mask and the optical deflector is coated with photoresist. Based on optical imaging theory (principle), the pattern is projected onto the optical waveguide material. Light passing through the mask and the lens reacts with the photoresist and leads to exposure. Then the exposed and unexposed photoresist on the optical deflector are treated by chemicals. Thus the pattern on the mask is transferred to the optical deflector completely. However, the photolithography used to produce optical deflectors includes many steps. The size of the optical deflector is quite small so that t the masks are very difficult to manufacture due to considerations of cost and size. Moreover, a −45 degrees slant is unable to be produced on the optical deflector manufactured by photolithography. Thus a further processing is required to produce the −45 degrees slant. This leads to increasing of the cost.

Another way to produce the optical deflector is by using femtosecond laser technology. In the beginning, a substrate is coated with a photoresist polymer film and then is set on a movable work platform or a rotatable work platform. Then a femtosecond laser is projected onto the photoresist polymer film to form an optical deflector. Once the optical deflector includes a −45 degrees slant, the work platform needs to be removed or rotated. Thus the manufacturing steps are increased and the production efficiency of the optical deflector is reduced.

There is a need to provide a manufacturing device of optical deflectors and a manufacturing method of the same by which the optical deflectors having −45 degrees slants are produced without complicated manufacturing processes so as to increase production efficiency.

### SUMMARY OF THE INVENTION

Therefore it is a primary object of the present invention to provide a manufacturing device of optical deflectors and a manufacturing method of the same that produce optical deflectors by using a femtosecond laser emitted from a femtosecond laser source to a photoresist polymer film at a non-focal position of a lens. Thus no complicated manufacturing processes are required and the production efficiency of the optical deflectors is improved.

In order to achieve the above object, a manufacturing device of optical deflectors includes a movable work platform, a substrate, a photoresist polymer film, a lens and a femtosecond laser source. The substrate is disposed on the movable work platform and is coated with the photoresist polymer film. The lens is located on one side of the movable work platform. The femtosecond laser source produces a femtosecond laser passing through the lens and projected onto the photoresist polymer film. Due to the position of the photoresist polymer film at the non-focal position of the lens, the optical deflector formed by the photoresist polymer film consists of a first light guide surface and a second light guide surface. The first light guide surface and the second light guide surface are planes or curved surfaces symmetrical to each other.

A manufacturing method of optical deflectors includes a plurality of steps. Firstly, provide a movable work platform. Then set a substrate on the movable work platform and the substrate is coated with a photoresist polymer film. Next provide a lens set on one side of the movable work platform. Use a femtosecond laser passing through the lens and projected onto the photoresist polymer film at the non-focal position of the lens so as to form an optical deflector. The optical deflector is produced by the femtosecond laser passing through the lens and emitted to the photoresist polymer film at the non-focal position. No complicated manufacturing processes are required. Thus the production efficiency of the optical deflector is increased.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein:

FIG. 1 is a schematic drawing showing an embodiment according to the present invention;

FIG. 2A is a schematic drawing showing structure of an optical deflector produced by an embodiment according to the present invention;

FIG. 2B is a schematic drawing showing structure of another optical deflector produced by an embodiment according to the present invention;

FIG. 3 is a schematic drawing showing another embodiment according to the present invention;

FIG. 4A is a schematic drawing showing structure of a further optical deflector produced by an embodiment according to the present invention;

FIG. 4B is a schematic drawing showing structure of a further optical deflector produced by an embodiment according to the present invention;

FIG. 5 is a flow chart showing manufacturing processes of an embodiment according to the present invention;

FIG. 6A is a schematic drawing showing optical deflection according to the present invention;

FIG. 6B is a schematic drawing showing optical deflection according to the present invention.

### DETAILED DESCRIPTION OF THE PREFERRED EMBODIMENT

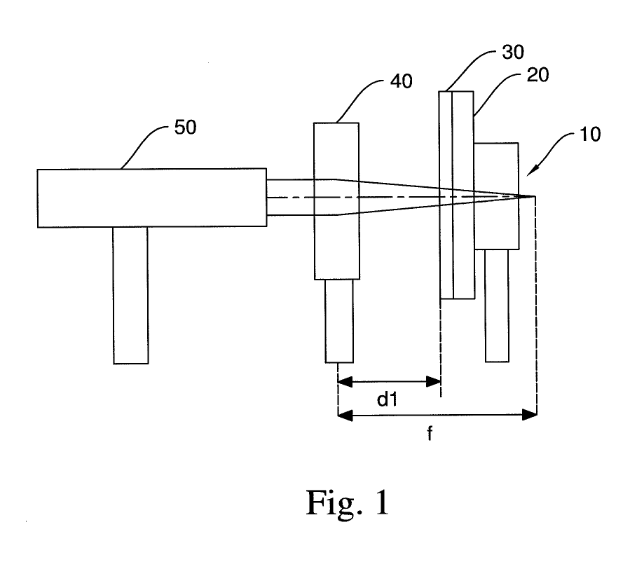

Refer to FIG. 1, a manufacturing device of optical deflectors includes a movable work platform 10, a substrate 20, a photoresist polymer film 30, a lens 40 and a femtosecond laser source 50. The optical deflector is applied to optical transmissions, such as transmission of light rays or transmission of optical waveguide.

The substrate 20 is disposed on the movable work platform 10 and is coated with a photoresist polymer film 30. The lens 40 is located on one side of the movable work platform 10. The photoresist polymer film 30 is on the position that is not the focus of the lens 40 (non-focal position). As shown in the FIG. 1A, the movable work platform 10 is fixed on a preset position that allows a first interval d1 between the photoresist polymer film 30 and the lens 40 while the first interval d1 is shorter than the focal length f of the lens 40. Thus a femtosecond laser emitted from the femtosecond laser source 50 is projected onto the photoresist polymer film 30 on the substrate 20 located at the non-focal position. Moreover, after the optical deflector being produced, a developer (not shown in the figure) is used to wash the photoresist polymer film 30 to get the optical deflector.

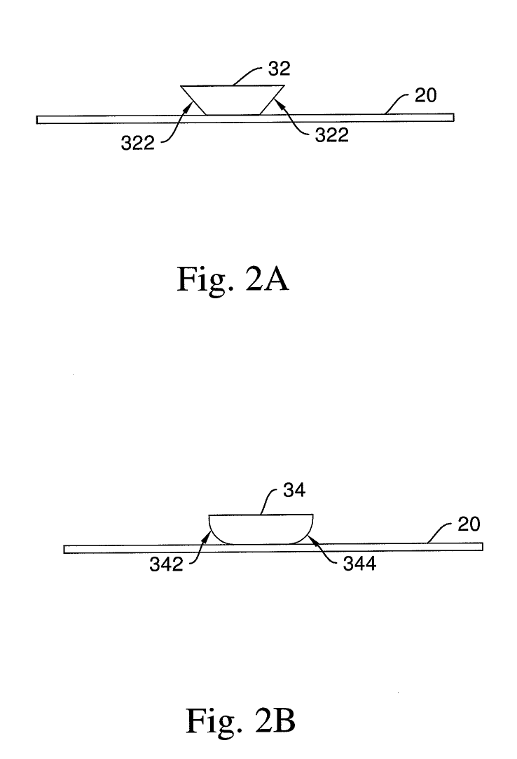

In this embodiment, the photoresist polymer film 30 is on the non-focal position and the first interval d1 is shorter than the focal length. After being projected by the femtosecond laser, the photoresist polymer film 30 becomes a first optical deflector 32 shown in FIG. 2A or a second optical deflector 34 shown in FIG. 2B. The first optical deflector 32 in FIG. 2A includes a first light guide surface 322 and a second light guide surface 324 while the first light guide surface 322 and the second light guide surface 324 are symmetrical planes. As to the second optical deflector 34 in FIG. 2B, it also includes a first light guide surface 342 and a second light guide surface 344 while the first light guide surface 342 and the second light guide surface 344 are curved surfaces symmetrical to each other.

The femtosecond laser source 50 generates optical pulses with duration on the order of 10⁻¹⁵ second. It's an important tool for research related to nonlinear optical experiments and ultrafast phenomena. The femtosecond laser source 50 can be a Cr:forsterite laser, a Ti:sapphire laser, etc. The Cr:forsterite laser is centered at 1230 nm with a 100 fs pulse-width. The output power is as high as 300˜500 mW with a 110 MHz repetition rate. The operating wavelength of the Ti:sapphire laser ranges from 700 to 900 nm. The output power is as high as 1.5 W with a shortest pulse width of 30 fs and a 2 GHz highest repetition rate. By crystal frequency doubling, blue or UV femtosecond pulses with the wavelength of 350 nm to 450 nm are generated. In combination with the optical parametric oscillator, the wavelength of femtosecond pulses can be extend to 1˜2 mm. In the present invention, the femtosecond laser source 50 is a Ti:sapphire femtosecond laser source 50.

The femtosecond laser source 50 induces two-photon absorption in polymer material so as to produce optical deflectors. Due to two-photon absorption induced by instantaneous power of the femtosecond laser 30, polymerization occurs in the photoresist polymer film 30. That means parts of the photoresist polymer film 30 emitted by the laser are exposed. Then use a developer to remove the rest of the photoresist polymer film 30 unexposed so as to get the optical deflector 32.

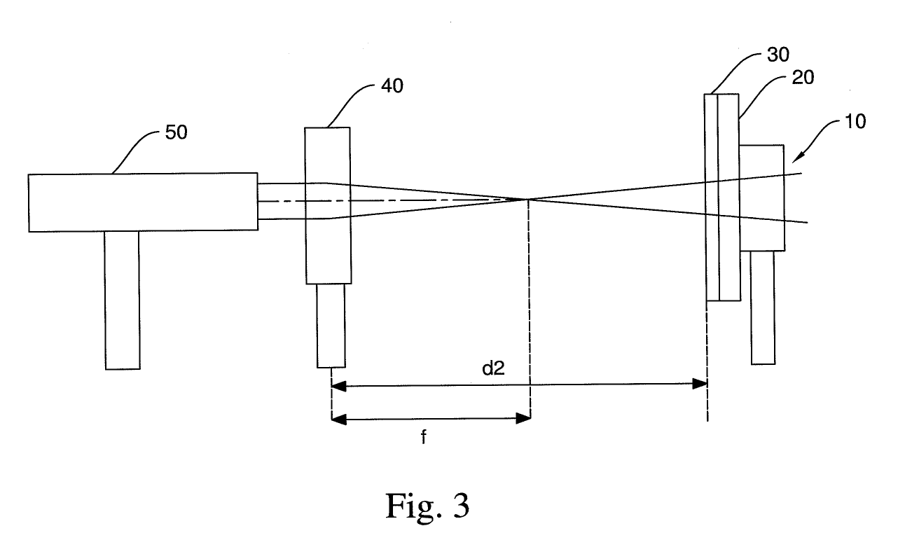

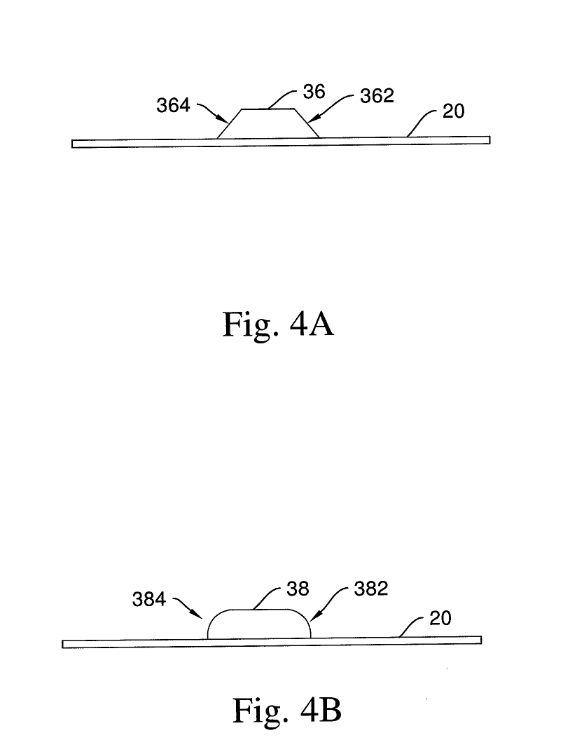

Refer to FIG. 3, another embodiment is revealed. The difference between this embodiment and the one in FIG. 1 is in that the position of the photoresist polymer film 30 in FIG. 1 is within the focal length f of the lens 40 (the first interval is shorter than the focal length f) while the position of the photoresist polymer film 30 in FIG. 3 is outside the focal length of the lens 40. As shown in the figure, the distance (interval) between the photoresist polymer film 30 and the lens 40 can be either shorter or longer than the focal length f. A second interval d2 between the photoresist polymer film 30 and the lens 40 is longer than the focal length f. Thus the photoresist polymer film 30 is emitted by the femtosecond laser at a non-focal position to produce at least one optical deflector. The optical deflector can be a third optical deflector 36 shown in FIG. 4A or a fourth optical deflector 38 shown in FIG. 4B.

In this embodiment, the photoresist polymer film 30 is located at a non-focal position and the distance between the photoresist polymer film 30 and the lens 40 is longer than the focal length f. After the photoresist polymer film 30 being emitted by the femtosecond laser, the third optical deflector 36 shown in FIG. 4A or the fourth optical deflector 38 shown in FIG. 4B is produced. The third optical deflector 36 in FIG. 4A includes a first light guide surface 362 and a second light guide surface 364 while the first light guide surface 362 and the second light guide surface 364 are planes symmetrical to each other. As to the second optical deflector 38 in FIG. 4B, it also includes a first light guide surface 382 and a second light guide surface 384 while the first light guide surface 382 and the second light guide surface 384 are symmetrical curved surfaces.

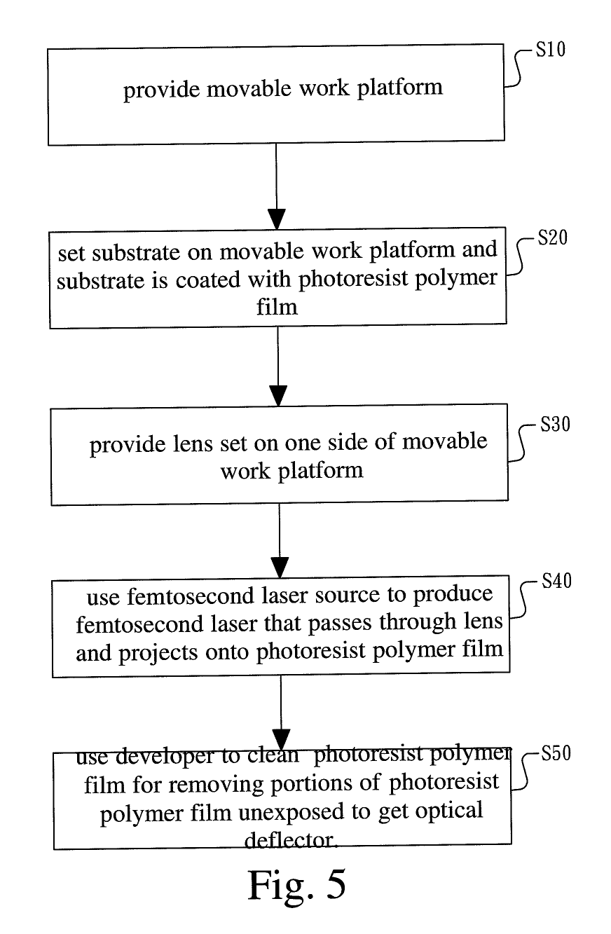

Refer to FIG. 5, a flow chart of an embodiment according to the present invention is revealed. As shown in the figure, while producing the optical deflector, firstly take the step S10, provide a movable work platform 10. Then refer to the step S20, set a substrate 20 on the movable work platform 10 and the substrate 20 is coated with a photoresist polymer film 30. The substrate 20 is made from silicon or silica. The photoresist polymer film 30 is made from epoxy resin (EPO). Next take the step S30, provide a lens 40 set on one side of the movable work platform 10. Then refer to the step S40, use a femtosecond laser source 50 to produce a femtosecond laser that passes through the lens 4 and projects onto the photoresist polymer film 30 at the non-focal position of the lens 4 so as to form an optical deflector. The wavelength of the femtosecond laser source 50 is having 790 nanometer wavelength, pulse width of 120 fs, pulse rate 80 MHz, average power of 1 W.

At last, run the step S50, use a developer to clean the photoresist polymer film 30 for removing portions of the photoresist polymer film 30 unexposed to get the optical deflector. Thus the optical deflector is produced by the femtosecond laser emitted from the femtosecond laser source 50 to the photoresist polymer film 30. The manufacturing processes are not complicated. Thus the simple manufacturing processes increase production efficiency of the optical deflector.

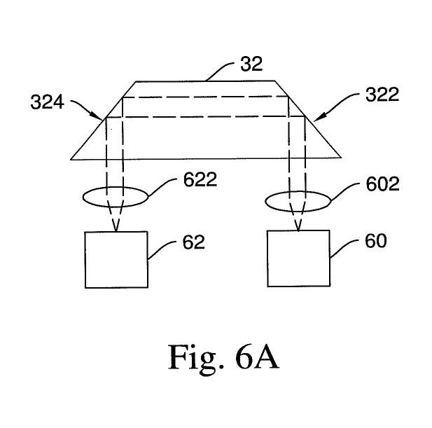

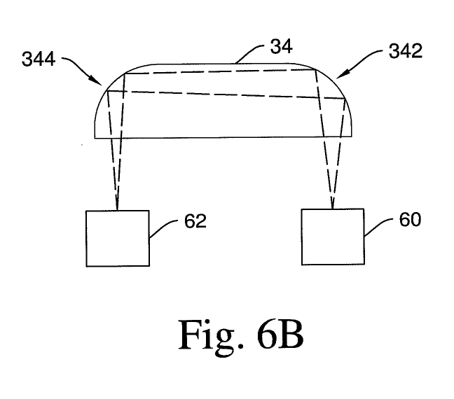

Refer to FIG. 6A, a schematic drawing showing changes of light path of an embodiment according to the present invention. As shown in the figure, an optical transmitter 60 and an optical receiver 62 are respectively arranged at a bottom of the first optical deflector 32. A first lens 602 is set between the optical transmitter 60 and the first optical deflector 32 while a second lens 622 is arranged between the optical receiver 62 and the first optical deflector 32.

The optical transmitter 60 emits light that passes through the first lens 602, and incident into the bottom of the first optical deflector 32, Then the light moves from the first light guide surface 322 toward the second light guide surface 324, then emergent from the second light guide surface 324 to the bottom of the first optical deflector 32, through the second lens 622 to be received by the optical receiver 62. On the other hand, if the positions of the optical transmitter 60 and the optical receiver 62 are exchanged, light from the optical transmitter 60 passes through the second lens 622 first, incident from the bottom of the first optical deflector 32 to the second light guide surface 324, through the first light guide surface 322, and emergent out of the bottom of the first optical deflector 32.

Refer to FIG. 6B, a schematic drawing showing changes of light path of another embodiment according to the present invention. The difference between the embodiment in the FIG. 6A and the one in the FIG. 6B is in that the first light guide surface 322 and the second light guide surface 324 are symmetrical planes while the first light guide surface 342 and the second light guide surface 344 are symmetrical curved surfaces. Moreover, there is no need to add a first lens and a second lens in the FIG. 6B. As shown in the figure, there is no first lens and no second lens set between the second optical deflector 34 and the optical transmitter 60/optical receiver 62 and the light can still be transmitted. The first light guide surface 342 and the second light guide surface 344 of the second optical deflector 34 provide better light gathering effect.

The difference between the third optical deflector 36/the fourth optical deflector 38 and the first optical deflector 32/the second optical deflector 34 is the way of formation on the substrate 20 while the light is deflected in similar way.

In summary, a manufacturing device of optical deflectors and a method of the same according to the present invention uses femtosecond laser emitted from femtosecond laser source to the photoresist polymer film at the non-focal position of the lens so as to produce optical deflectors. The optical deflector includes a first light guide surface and a second light guide surface that are planes or curved surfaces symmetrical to each other. The manufacturing processes are not complicated so that the production efficiency of the optical deflector is increased.

Additional advantages and modifications will readily occur to those skilled in the art. Therefore, the invention in its broader aspects is not limited to the specific details, and representative devices shown and described herein. Accordingly, various modifications may be made without departing from the spirit or scope of the general inventive concept as defined by the appended claims and their equivalent.

What is claimed is:

1. A manufacturing device of optical deflectors comprising:
a movable work platform;
a substrate disposed on the movable work platform and coated with a photoresist polymer film;
a lens located on one side of the movable work platform and the photoresist polymer film being set on a non-focal position of the lens;
a femtosecond laser source set on one side of the lens and producing a femtosecond laser that passes through the lens and projects onto the photoresist polymer film at the non-focal position so as to produce at least one optical deflector; the optical deflector includes a first light guide surface and a second light guide surface; the first light guide surface and the second light guide surface are planes or curved surfaces symmetrical to each other.

2. The device as claimed in claim 1, wherein the substrate is made from silicon, silica or their combinations.

3. The device as claimed in claim 1, wherein the photoresist polymer film is made from epoxy resin (EPO).

4. A manufacturing method of optical deflectors comprising the steps of:
providing a movable work platform;
setting a substrate on the movable work platform and coating a photoresist polymer film over the substrate;
providing a lens arranged at one side of the movable work platform; and
using a femtosecond laser that passes through the lens and projects onto the photoresist polymer film at a non-focal position of the lens so as to form at least one optical deflector; the optical deflector includes a first light guide surface and a second light guide surface; the first light guide surface and the second light guide surface are planes or curved surfaces symmetrical to each other.

5. The method as claimed in claim 4, wherein the method further having a step of:
using a developer to wash the optical deflector.

6. The method as claimed in claim 4, wherein the substrate is made from silicon, silica or their combinations.

7. The method as claimed in claim 4, wherein the photoresist polymer film is made from epoxy resin (EPO).
